(19) United States
(12) Patent Application Publication
(10) Pub. No.: US 2009/0239314 A1
(43) Pub. Date: Sep. 24, 2009

(54) Methods of Manufacturing a Semiconductor Device

(76) Inventors: Martin Haberjahn, Dresden (DE); Sascha Dieter, Ottendorf-Okrilla (DE); Andrea Graf, Dresden (DE); Christoph Noelscher, Nuernberg (DE); Dirk Manger, Dresden (DE); Stephan Wege, Dresden (DE)

Correspondence Address: SLATER & MATSIL, L.L.P., 17950 PRESTON ROAD, SUITE 1000, DALLAS, TX, 75252, US

(21) Appl. No.: 12/051,932

(22) Filed: Mar. 20, 2008

(51) Int. Cl. H01L 21/66

(52) U.S. Cl. 438/8; 438/7; 257/E21.528

(57) ABSTRACT

Methods of manufacturing a semiconductor device and an apparatus for the manufacturing of semiconductor devices are provided. An embodiment regards providing a process which changes the volume of at least one layer of a semiconductor substrate or of at least one layer deposited on the semiconductor substrate, and measuring a change in volume of such at least one layer using fluorescence. In another embodiment, a change in volume of such at least one layer is measured using reflection of electromagnetic waves.

### TECHNICAL FIELD

The present inventions generally relates to the manufacturing of semiconductor devices.

### BACKGROUND

In semiconductor manufacturing, a photoresist pattern is produced by imaging a reticle pattern on a photoresist and developing the photoresist. Afterwards, etching is conducted to transfer the photoresist pattern to the underlying layer. These steps are repeated multiple times to produce a multi-layer semiconductor device. Also, a hard mask pattern may be used to structure an underlying layer.

There is a general desire to monitor and control etching and material deposition processes that occur during semiconductor manufacturing. For example, end point detection during etching is required to produce a desired critical dimension (CD).

### SUMMARY OF THE INVENTION

One embodiment provides a method of manufacturing a semiconductor device. At least one structured layer is produced in a semiconductor substrate. During such producing of at least one structured layer, there is provided at least once a process which changes the volume of at least one layer of the semiconductor substrate or of at least one layer deposited on the semiconductor substrate. Such process could be an etching process or a deposition process. It is measured a change in volume of such at least one layer using fluorescence. For example, a signal indicative of the intensity of X-Ray fluorescence may be determined.

In another embodiment, there is also provided during the producing of at least one structured layer in a semiconductor substrate a process which changes the volume of at least one layer of the semiconductor substrate or of at least one layer deposited on the semiconductor substrate. In this embodiment, it is measured a change in volume of such at least one layer using reflection of electromagnetic waves. For example, X-Rays reflected by the substrate are measured and a signal is provided indicative of the intensity of the reflected X-rays.

In another embodiment, there is provided a method of manufacturing a semiconductor device in which there is provided a top first layer of a semiconductor substrate and a second layer of the semiconductor substrate beneath the first layer, the two layers having a different refractive index for X-Ray radiation. The first layer of the semiconductor substrate is etched. During etching, the substrate is irradiated with X-Rays. The X-Rays reflected by the substrate are measured and it is provided a signal indicative of the reflected X-rays. It is determined a change in the signal and an end point of the etching process is associated with the change in the signal. The change in signal is caused by a changed reflectivity when the material of the first layer is at least partly etched away and the X-Rays are then at least partly reflected by the second layer.

In another embodiment, there is provided a method of manufacturing a semiconductor device which comprises a process which etches a top first layer of a semiconductor substrate or produces such layer, wherein a second layer of the semiconductor substrate is located beneath the first layer. The materials of the first and second layers and the angle of incidence of the incident X-Rays are chosen such that total reflection of the incident X-Rays occurs or disappears when at least a part of the first layer has been processed. The occurrence or disappearance of total reflection corresponding to an increase or drop in the intensity of the reflected X-Rays, which corresponds to the end of the etching or layer producing process. The method may be used for end point detection. Accordingly, in this embodiment, the occurrence or disappearance of total reflection of X-Rays is an indication of the completion of a process step.

A further embodiment regards an apparatus for the manufacturing of semiconductor devices. The apparatus comprises means for changing the volume of at least one layer of a semiconductor wafer or of at least one layer deposited on the semiconductor wafer, an X-Ray radiation source, an X-Ray detection device detecting and measuring a signal indicative of the intensity of X-Rays reflected or emitted by fluorescence by the semiconductor wafer, and evaluating means for associating the signal with the course of the change in volume process.

### BRIEF DESCRIPTION OF THE DRAWINGS

The drawings show different exemplary embodiments and are not to be interpreted to limit the scope of the invention.

FIG. 1 schematically shows an embodiment of an apparatus for manufacturing of semiconductor devices, the apparatus measuring a change in volume of at least one layer of a semiconductor substrate using X-ray fluorescence or X-ray reflection;

FIG. 2A schematically an embodiment in which a change in volume of a semiconductor layer is measured using X-ray fluorescence, wherein a first signal is measured;

FIG. 2B schematically an embodiment in which a change in volume of a semiconductor layer is measured using X-ray fluorescence, wherein a second signal is measured;

FIG. 3 a graph showing process control parameters in dependence on the difference of fluorescence intensities as measured in accordance with FIGS. 2a, 2b;

FIG. 4A schematically a further embodiment of an apparatus for the manufacturing of semiconductor devices, the apparatus having a tunable angle of incidence;

FIG. 4B an embodiment similar to FIG. 4A, wherein X-rays are incident parallel to elongated structures on the top layer of a semiconductor device;

FIG. 5A an example application of a change in volume process, wherein a pattern is etched into a substrate;

FIG. 5B another example application for a change in volume process, wherein a structure is widened;

FIG. 5C another example of a change in volume process, wherein a structure is thinned;

FIG. 5D another example of a change in volume process, wherein a structure is etched into a top layer without breaking through the top layer;

FIG. 5E another example application of a change in volume process, wherein a structure is etched into a top layer with a break through the top layer;

FIG. 5F a top view of etched lines and spaces;

FIG. 5G a top view of etched holes;

FIG. 6A schematically the refraction of X-rays at the passage from vacuum to matter, including an indication of the critical angle of total reflection;

FIG. 6B a graph showing the reflected intensity of X-rays in dependence of the incidence angle for two materials having a different refractive index;

FIG. 7 an embodiment of an in-situ process in which the etching of lines and spaces is monitored using X-ray reflection;

FIG. 8 an embodiment of an in-situ process in which a line etch is monitored using X-ray reflection;

FIG. 9 a graph showing the reflected intensity in dependence on the incident angle in a simulation of the reflectivity data of FIG. 7;

FIG. 10 a graph showing reflected intensity in dependence of the thickness of a deposition layer;

FIG. 11 a flow chart indicating the steps of an embodiment of a method of manufacturing a semiconductor device;

FIG. 12 a flow chart indicating the steps of a further embodiment of a method of manufacturing a semiconductor device;

FIG. 13 a flow chart indicating the steps of a further embodiment of a method of manufacturing a semiconductor device; and

FIG. 14 a flow chart indicating the steps of a further embodiment of a method of manufacturing a semiconductor device.

### DETAILED DESCRIPTION OF ILLUSTRATIVE EMBODIMENTS

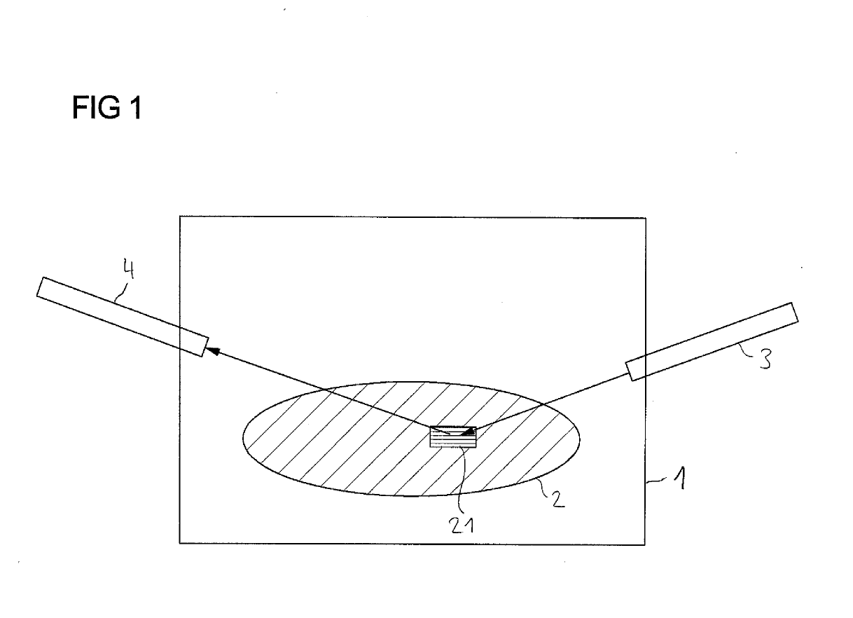

FIG. 1 shows an embodiment of an apparatus which comprises an etch chamber 1 used in the process of manufacturing a semiconductor device. The etch chamber 1 comprises a chuck (not shown) supporting a semiconductor wafer 2. As is well-known to those skilled in the art, the etch chamber also includes an upper electrode and a lower electrode (not shown). Inside the etch chamber 1 and between the electrodes, a gas plasma is provided. It is pointed out that etch chamber 1 is an example of an etch chamber only. Other etch chambers using other etching processes than plasma etching such as, e.g., ion beam etching or electron-induced reactive etching may be implemented as well.

The apparatus further comprises an X-ray radiation source 3 and an X-ray detection device 4. In one embodiment, the X-ray radiation source 3 provides at least one incident X-ray beam of a specified spot size. In one embodiment, the X-ray radiation source 3 is adapted to scan at least a top layer of the wafer 2 with the incidence beam. In the embodiment of FIG. 1, there is schematically depicted an area 21 which represents a spot size. Incident light from the X-ray source 3 is either reflected in the area 21 of wafer 2 or an X-ray fluorescence signal is produced in the area 21. The two different mechanisms of either X-ray reflection or X-ray fluorescence will be explained in more detail below.

It is pointed out that in other embodiments the X-ray radiation source 3 may not be scanning the wafer 2 but, e.g., illuminating the complete wafer 2. Also, embodiments exist in which a sample volume that is representative of the wafer is irradiated only, without irradiating other areas.

The X-ray detection device 4 detects the signal that is reflected or emitted by fluorescence by area 21 of the semiconductor wafer when irradiated with X-rays by the X-ray radiation source 3. The detection device 4 includes evaluating means for associating the signal with a change in volume that is applied to at least one layer of the semiconductor wafer during a process. The evaluating means may also be provided in a separate unit.

The X-ray radiation source 3 and the X-ray detection device 4 are located either inside or outside the etch chamber 1. In one embodiment, they are located inside the etch chamber 1.

It is pointed out that there may be several detection devices and several X-ray sources located at different angles and with different wavelengths. There may also be provided a control system (not shown) that gives feedback to the process during etch or deposition. The system may be used in-situ or ex-situ and may give feedback for etch of the actual or next wafer.

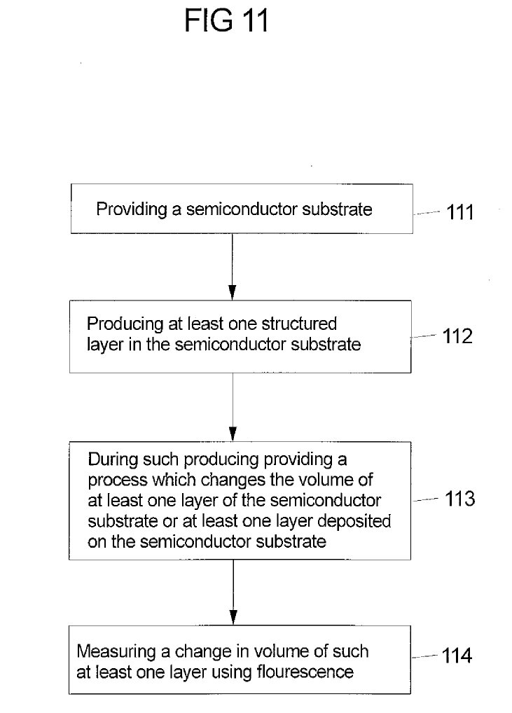

The apparatus shown in FIG. 1 is suitable to carry out a plurality of methods which regard the measurement of a change in volume in at least one layer of the semiconductor wafer 2 by means of processes involving X-ray fluorescence or X-ray reflection. Also, a combination of X-ray fluorescence and X-ray reflection may be carried out. FIGS. 11 to 14 depict general embodiments of such methods.

According to FIG. 11, in a first step 111 a semiconductor substrate is provided. In step 112 there is produced at least one structured layer in the semiconductor substrate. According to step 113, during such producing of at least one structured layer, there is provided a process which changes the volume of at least one layer of the semiconductor substrate or of at least one layer deposited on the semiconductor substrate. A deposited structure could be, e.g., a photoresist. According to step 114 there is measured a change in volume of the at least one layer using fluorescence.

Such fluorescence in one embodiment is X-ray fluorescence. In other embodiments, instead of X-rays, electromagnetic waves of other wavelengths may be used for exciting fluorescence such us UV light.

X-ray fluorescence (XRF) occurs when materials are exposed to high energetic radiation such as X-ray radiation or Gamma-ray radiation. Following ionization, electrons in higher orbitals fall into the lower orbital to fill the hole left behind. In falling, energy is released in the form of a photon. This so-called fluorescence radiation is characteristic for the atoms present. Further, the fluorescence intensity is directly related to the amount of each material in a given sample.

In the embodiment of FIG. 11, fluorescence is used in controlling the volume of a probed material. A change in volume is measured and used for process monitoring. It is pointed out that with a known density a change in volume is equivalent to a mass change. Accordingly, volume change and mass change are equivalent.

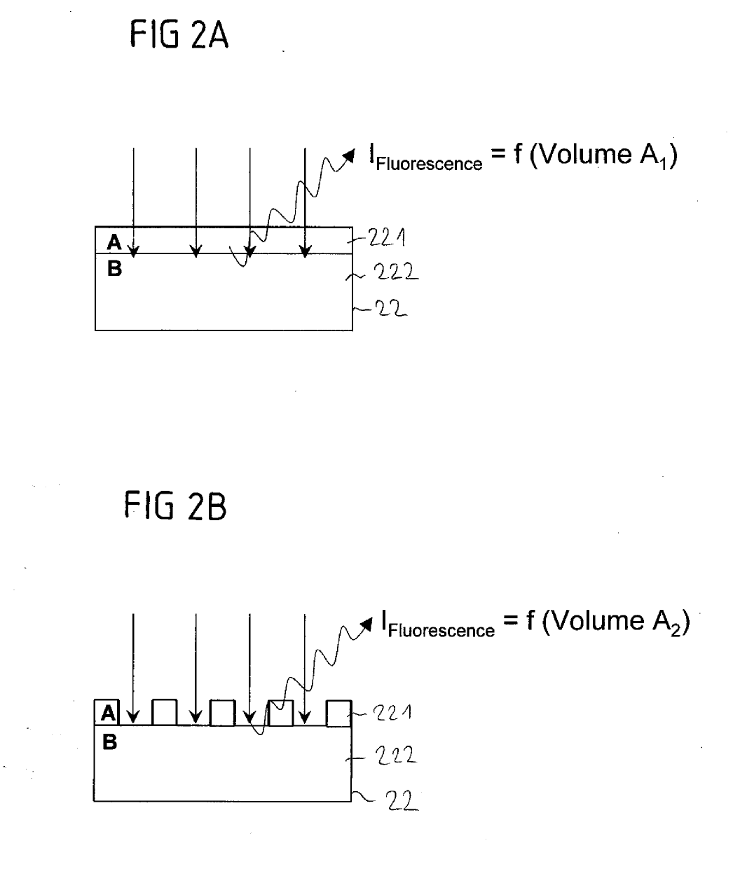

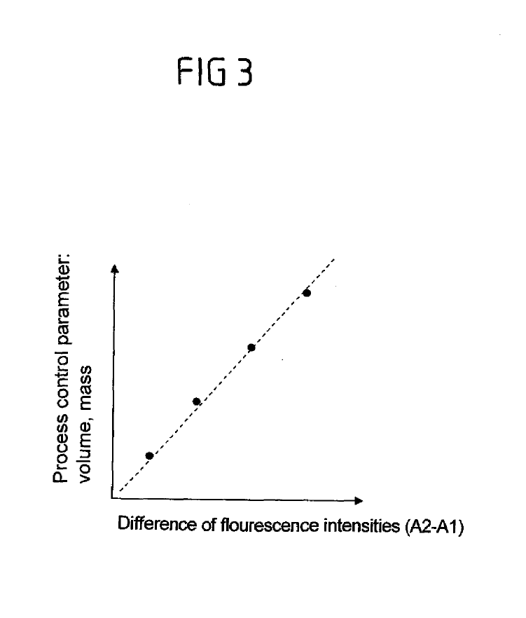

FIGS. 2A, 2B and 3 show a possible example of a method using X-ray fluorescence. According to FIG. 2A, there is provided a sample volume 22 comprising two layers, a top layer 221 and an underlying layer 222. The top layer 221 comprises a material A and the other layer 222 comprises a material B. In FIG. 2a, a first measurement is carried out previous to the process that leads to a change in volume of layer 221 such as an etching process. The intensity of a first fluorescence signal is measured. This intensity depends on the volume A₁ of the layer 221 before the change in volume. After the change in volume, a measurement post to the process is carried out, see FIG. 2B. Such post measurement yields a second value for the intensity of the fluorescence which is dependent on the changed volume A₂. In the example of FIGS. 2A, 2B, the volume of the first layer 221 has decreased such that the intensity of the fluorescence signal has decreased as well.

Alternatively, measurements are made at other or additional times between start and end of a process that leads to a change in volume. Also, measurements may be taken essentially continuously to allow endpoint detection.

According to FIG. 3, the relative measurements can be extended to obtain absolute values by using a calibration between intensity differences (pre/post measurement according to FIGS. 2A, 2B) and the parameter of interest such as volume and mass. Using such calibration, the measured intensity can be evaluated in terms of a process control parameter.

The sensitivity of this method will be dependent on the ratio between the depth up to which a volume change is introduced into the sample and the depth from which fluorescence radiation can be collected and evaluated (in the following referred to as information depth). The lower this ratio, the higher the sensitivity.

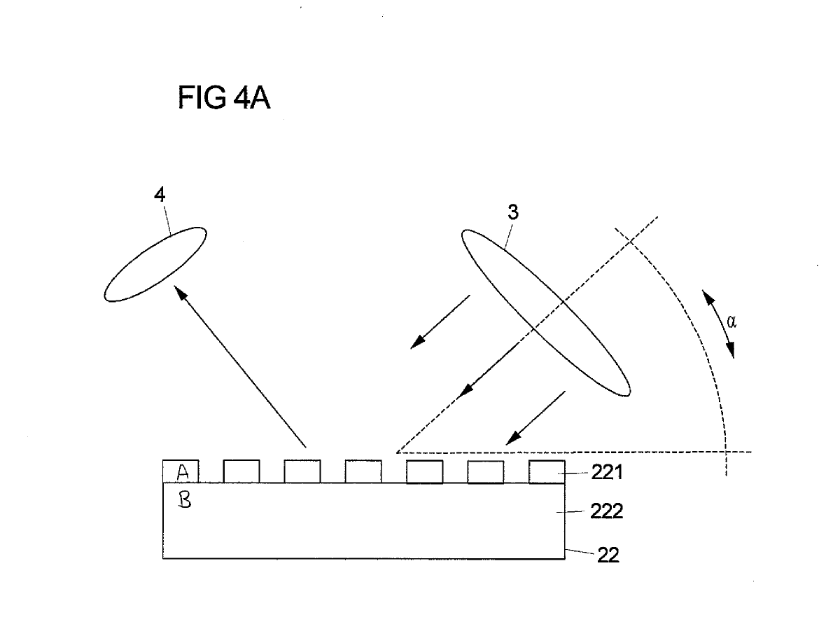

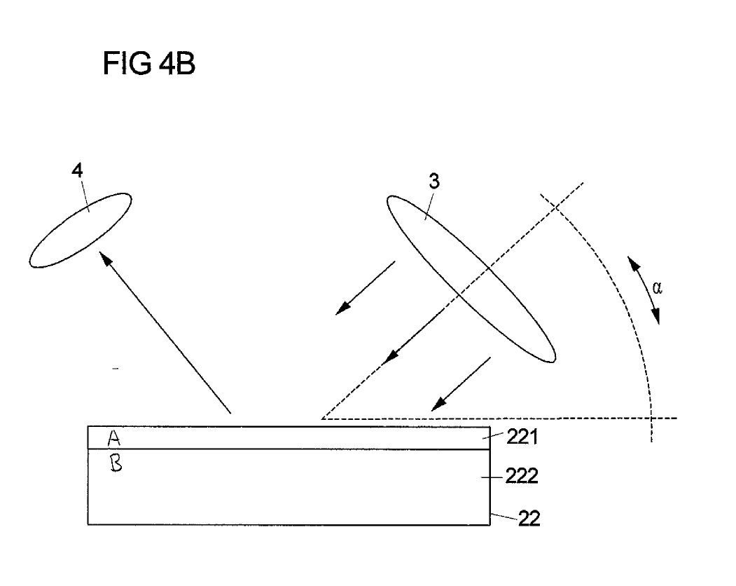

The information depth may be customized by using grazing incidence primary X-ray radiation. FIG. 4A shows parts of an apparatus used in the process of manufacturing a semiconductor device which is largely similar to the apparatus of FIG. 1. With apparatus of FIG. 4A, the penetration depth of the incidence beam and thus the information depth of the fluorescence radiation can be tuned by the angle of incidence α. The angle of incidence a may be tuned between the angle of total reflection and an angle of normal incidence dependent on the material properties.

More particularly, in FIG. 4A there is provided a sample volume 22 which is part of a semiconductor wafer such as semiconductor wafer 2 of FIG. 1. The sample volume 22 includes a first layer 221 of material A and a second layer 222 of material B which is beneath the first layer 221. There is further provided an X-ray source 3 and a detector system 4.

X-rays from source 3 are radiated on the sample 22. The signal detected by detector system 4 is formed by fluorescence signals from material A of layer 221 and material B of layer 222. However, the collected fluorescence signal comes mainly from the upper layer 221 of etched structures, particularly, before the etching of the top layer 221 has been completed. The penetration depth of the primary X-rays of source 3 may be tuned by varying the angle of incidence α.

As more and more material A is etched away during etching, the fluorescence signal of layer 221 is reduced, until a minimum is reached. Further, eventually, an additional fluorescence signal from material B of layer 222 becomes stronger in the course of the etching process. By determining the minimum of the fluorescence signal from material A and/or determining the fluorescence signal of material B, the course of the etching process can be followed. This can be used, for example, for endpoint detection of the etching process.

Similar remarks apply in case a layer of material is deposited. With increased deposition, the fluorescence signal of the deposited material increases.

According to the described method, direct measurement of volume or mass change is possible. The volume change can be obtained locally as the fluorescence signal can be restricted to a sample volume which is defined by the spot size of the XRF times the information depth of the fluorescence radiation. As the X-ray radiation is local, the fluorescence signal is also local and this way a spatial resolution of the signal is naturally provided for.

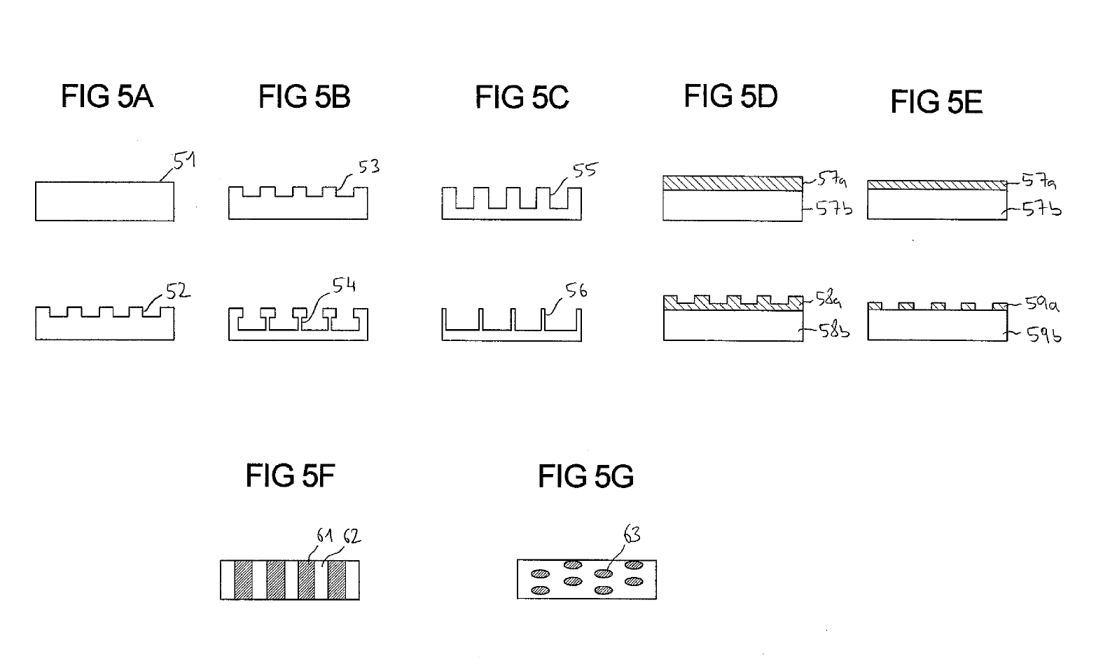

FIGS. 5A to 5E show sample applications of processes which change the volume of a substrate or the top layer of the substrate. In FIGS. 5A to 5E, the top drawing shows the substrate before the process and the bottom drawing shows the substrate after the process.

According to FIG. 5A, a pattern 52 is etched into a flat surface 51 of the substrate. According to FIG. 5B, a structure 53 is widened to a structure 54. According to FIG. 5C, a structure 55 is thinned to a structure 56. According to FIG. 5D, a substrate having a top layer 57a and a bottom layer 57b is structured such that the top layer 58a only receives a pattern by etching, without breaking through the top layer 58a. In FIG. 5E, the starting situation is the same as in FIG. 5D. During the etching step, however, structure 59a is provided to top layer 57a with break through the top layer.

FIG. 5F shows a top view of etched lines and spaces, as provided, for example, by processes in accordance with FIGS. 5A to 5E. FIG. 5G shows a top view of a structure having etched holes 63.

In all of the structures shown in FIGS. 5A to 5G, the structuring includes a change in volume process which may be monitored using X-ray fluorescence.

In the following, a further embodiment of a method for manufacturing a semiconductor device using X-ray fluorescence to measure a change in volume of at least one substrate layer is discussed. This method has already been indicated with respect to FIG. 4A according to which there is a top first layer 221 the volume of which is changed during the process and an underlying second layer 222 the layer of which is not changed during the process. The first layer comprises a first material A having a fluorescence radiation with a first wavelength and a second layer comprises a second material having a fluorescence radiation with a second wavelength, wherein both layers are subjected to X-ray radiation.

In this embodiment, other than in the embodiment previously described with respect to FIG. 4A, the focus is on the signal of the underlying second layer. It is thus considered an X-ray radiation with a penetration depth that is suitable to penetrate also the second layer 222. To this end, the angle of incidence a may be adjusted appropriately.

In such embodiment, the fluorescence signal of the second layer 222 may be evaluated to determine the end point of the change in volume process. For example, if a change in volume process is an etching process such as in FIG. 4A, the fluorescence signal of the second layer is measured and an end point detected when the fluorescence signal of the second layer reaches a specific strength, such strength indicating a specific open area of the second layer produced by the etching of the first layer.

According to this embodiment, a fluorescence signal is detected which is representative of an open area of a substrate layer which is beneath the substrate layer that has been subject to an etching or other process. The intensity of the emission from the layer below the etched layer is a measure of the open area and, therefore, a measure of the etched critical dimension at the measuring spot.

Such measurement may be made for sample volumes by scanning an incident X-ray beam over the wafer as discussed before. Also, one averaging measurement for the complete wafer may be carried out.

In an embodiment, such open area fluorescence signal measurement is implemented for a spacer etch in the course of a double patterning process, for example below 40 nm half-pitch. With a spacer etch, the direction of the incident X-rays in one embodiment is parallel to the respective lines. FIG. 4B shows such embodiment. Apart from the direction of the incident X-rays, FIG. 4B is similar to FIG. 4A.

With spacer etches, if the etch is too long, the spacer becomes too small, if it is too short, the spacer becomes too wide. Further, there is usually a non-uniformity over the wafer and the shape of the spacer can vary. Therefore, exact control during etch is required to provide for a desired critical dimension (CD). A measurement as discussed above provides end point detection that allows to control such etch. The integrated intensity over a defined dose and defined pattern is sufficiently precise to calibrate a critical dimension versus signal curve for, e.g., a sub-40 nm patterning, especially for sublithographic patterning techniques.

In one embodiment, this method provides for a kind of “0-1” transition, the “1-signal” occurring when the top layer has been partially etched through such that the fluorescence signal of the second layer gains importance.

The above embodiment similarly applies for deposition processes, in which the signal from an underlying layer is being reduced in the course of deposition, or the signal from the deposited layer is being increased.

As all methods described in this text, the method can be applied in in-situ but also ex-situ.

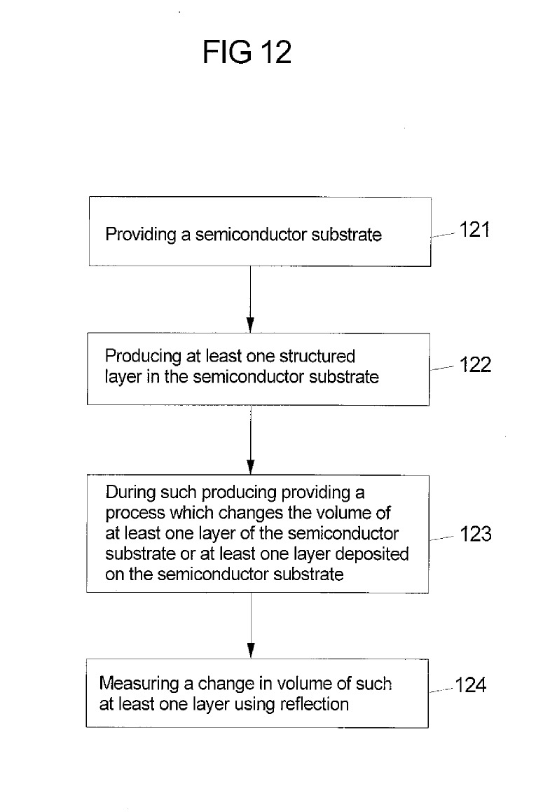

FIG. 12 shows a further example of a method for producing a semiconductor device. The method includes a first step 121 in which a semiconductor substrate is provided. There is further provided a second step 122 in which at least one structured layer in the semiconductor substrate is produced. Further, in step 123 a process which changes the volume of at least one layer of the semiconductor substrate or of at least on layer deposited on the semiconductor substrate is carried out. In step 124, the change in volume of such at least one layer is measured using reflection of electromagnetic waves. Such electromagnetic waves may be, but are not limited to, X-Rays.

For example, the semiconductor substrate has a top first layer and a second layer beneath the first layer, the two layers having a different refractive index. When the top first layer has been etched away or partially been etched away, the X-rays are reflected at least partially by the second layer, this leading to a different signal.

Accordingly, in this embodiment, X-ray reflection is used for measurement instead of X-ray fluorescence. However, measurement of X-ray reflection may be combined with measurement of X-ray fluorescence as described above. Further, in other embodiments, instead of X-rays, electromagnetic waves of other wavelengths may be used for reflection such us UV light.

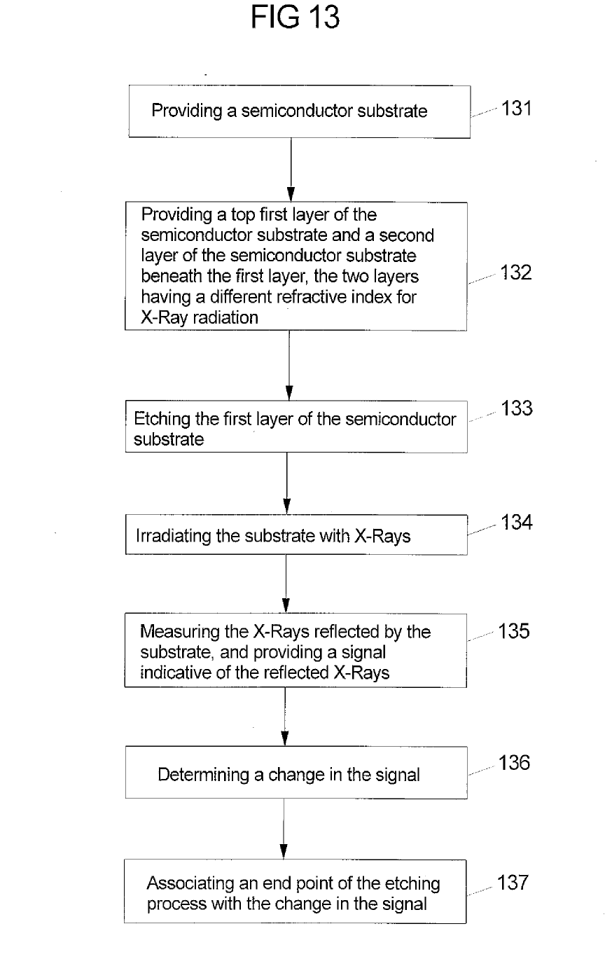

FIG. 13 shows a more detailed embodiment of a method for manufacturing a semiconductor device using X-ray reflection to measure a change in volume of a substrate layer. According to FIG. 13, in step 131, a semiconductor substrate is provided. In step 132, there is provided a top first layer of the semiconductor substrate and a second layer of the semiconductor substrate beneath the first layer, the two layers having a different refractive index for X-Ray radiation. In step 133, the first layer of the semiconductor substrate is etched. The substrate is irradiated with X-Rays, step 134, and the X-Rays reflected by the substrate are measured, step 135. There is provided a signal indicative of the reflected X-rays, step 135. A change in the signal is determined, step 136, and an end point of the etching process is associated with the change in the signal, step 137. The change in signal is caused by a changed reflectivity when the material of the first layer is at least partly etched away and the X-Rays are then at least partly reflected by the second layer.

In an embodiment of the method of FIG. 13, the material of the first layer is chosen such that it has a first critical grazing angle of total reflection for X-Ray radiation and the material of the second layer is chosen such that it has a second critical grazing angle of total reflection for X-Ray radiation, wherein the second critical angle is smaller than the first critical angle. X-Rays are irradiated at the substrate at a grazing angle of incidence that is smaller than the first critical angle of total reflection for the material of the first layer and larger than the second critical angle of total reflection for the material of the second layer.

Accordingly, before material of the first layer is etched away, total reflection of the incident X-Rays occurs at this material, and when material of the first layer has been etched away, the X-Rays are incident on the material of the second layer where they do not experience total reflection. This corresponds to a drop in reflected intensity which can be associated with an end point of the etch.

The method of FIG. 13 provides for an in-situ control of a plasma etching process and the determination of an end point of the etching process by means of a reduction in reflected intensity due to a loss or reduction of total reflection after the top layer has been etched.

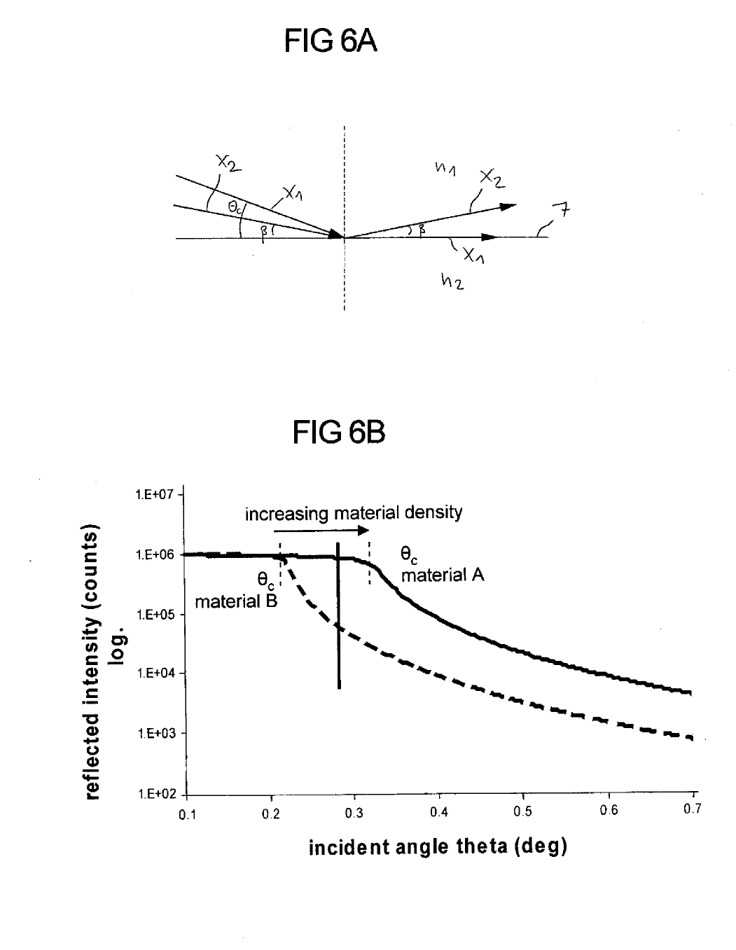

This embodiment will be better understood in the context of the examples of FIGS. 6a to 10.

FIG. 6A shows the situation involved in total reflection. There are provided two materials having a refractive index of n1 and n2, respectively. The boundary between the two materials is designated by reference sign 7. In the present case, the material of refractive index nil is vacuum (or gas or plasma). The material of refractive index n2 is a material subjected to a change in volume process. Due to the fact that for X-rays the real part of the refractive index in vacuum (as well as in gas and plasma) is greater than the real part of the refractive index of a solid material, nil (vacuum, gas, plasma) is larger than n2 (solid).

Grazing angle θ_{C} indicates the angle of total refraction. X-ray X1 irradiated with that angle on the boundary 7 runs parallel to the boundary 7 and is not refracted into material with refractive index n2. All X-rays with an angle of incidence smaller than the critical angle of incidence θ_{c}, such as X-ray X2 with angle of incidence β, are totally reflected at boundary 7.

According to FIG. 6B, the value of the critical angle θc varies with material density, wherein the material density is connected to the refractive index, such that the value of the critical angle θc varies with the refractive index of the respective material. The angle of incidence of the X-rays of X-ray source 3 (see FIG. 1) is chosen such that it lies between the critical angles for material A of the first, top layer and for material B of the second, underlying layer. In other words, the material A of the first layer is chosen such that it has a first critical grazing angle of total reflection for X-ray radiation, the material B of the second layer is chosen such that it has a second critical grazing angle of total reflection for X-ray radiation, wherein the second critical angle is smaller than the first critical angle. X-rays are now irradiated at the substrate at a grazing angle of incidence that is smaller than the first critical angle of total reflection for the material of the first layer and larger than the second critical angle of total reflection for the material of the second layer.

Accordingly, incident X-rays are totally reflected as long as the second layer is covered by material of the first layer. Once the material of the first layer has been etched away, the prerequisites for total reflection are not present anymore such that total reflection is stopped in those areas in which the material of the first layer has been removed. This corresponds to a drop in reflected intensity, which may be sharp. This drop in reflected intensity is measured by the X-ray detection device 4 (see FIG. 1). The drop in reflected intensity indicates the endpoint of the etching step.

Accordingly, as long as there is material A on the surface, total reflection occurs. When material A is removed, e.g. by plasma etching, the reflected intensity will drop down significantly, because the radiation will now enter material B where no total reflection happens. The corresponding signal indicative of the reflected X-rays will thus experience a change as well. In particular, such signal may experience a sharp (non-gradual) reduction or drop-off that can be associated with an end point of the etching process.

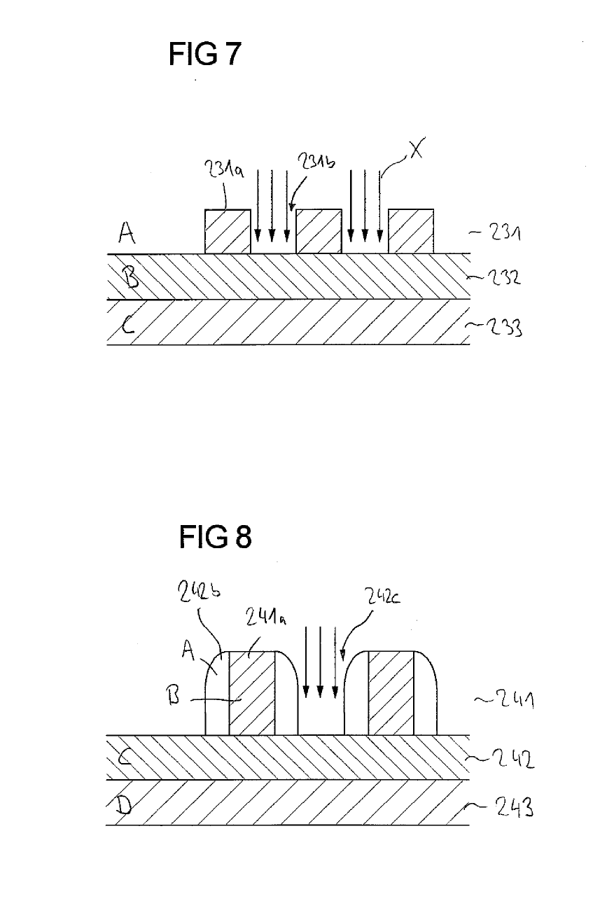

FIG. 7 shows an example application indicating an in-situ process for monitoring the etching of the lines and spaces. There are provided three layers in a sample volume, a top layer 231 comprising a first material A, an intermediate layer 232 comprising a material B and a bottom layer 233 comprising a material C. In the top layer 231, lines 231a and spaces 231b are etched. FIG. 7 shows the top layer 231 after the etching process has been finished.

The direction of the incident X-rays is parallel to the lines 231a and spaces 231b, as indicated by arrows X. Before the material A of layer 231 has been etched away in the spaces 231b, total reflection in these areas occurred. After the spaces 231b have been etched, incident X-rays are not further totally reflected in these areas but will at least partly enter material B of layer 232, this corresponding with a change in the reflected intensity which can be evaluated to identify the endpoint of the etching process.

FIG. 8 shows another embodiment regarding an in-situ process for monitoring a liner etch in the course, e.g., of double patterning.

Again, there is provided a top layer 241, an intermediate layer 242 and a bottom layer 243. The top layer 241 includes lines 241a which comprise material B. At the sides of the lines, spacers 242b of material A are formed. Between the lines 241a and the spacers 241b spaces 242c are present. The intermediate layer 242 comprises material C and the bottom layer 243 comprises material D.

Again, in FIG. 8, the situation when the etching process has ended is shown. As in FIG. 7, there is a decline in reflected intensity when material previously in the area of spaces 242c has been etched away such that total reflection does not occur anymore in these areas.

Examples for the materials A, B, C and D in FIGS. 7 and 8 are as follows: Material A may be TiN, Ge, GeO₂, Ta, TaN, TaOₓ, W, WOₓ, TiOₓ, MoSi, CoSi and Cu. Material B may be Si, SiOₓN_{y}, polymer and Ge. Material C may be Si₃N₄, TiN, Al₂O₃, Al, Cu or Si. Material D may be C.

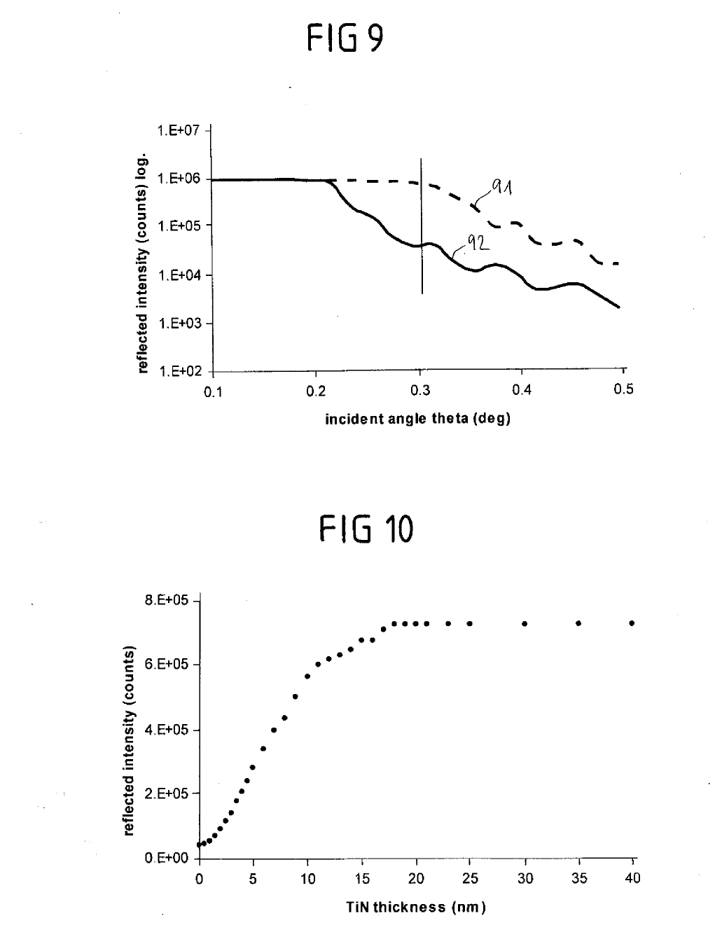

FIG. 9 shows the reflected intensity in dependence on the incident angle for two different materials. With an assumed angle of incidence θ_{c} of 0.3 deg, the reflected intensity is considerably higher for the material of dashed line 91 compared to the material of solid line 92. The material of dashed line 91 is material A of FIG. 7. Solid line 92 represents material B of FIG. 7. Accordingly, if incident X-rays are reflected at material A (along the lines 231a of FIG. 7), the reflected intensity is more than ten times higher compared to when the incident X-rays are reflected at material B (along spaces 231b of FIG. 7).

FIG. 10 shows the reflected intensity in dependence of the thickness of a layer which is deposited on an underlying layer. Again, the reflected intensity is measured at an angle of incidence θ_{c} of 0.3 deg. As the thickness of the layer grows, the reflected intensity grows as well, as the newly deposited layer now provides for total reflection of the incident X-rays.

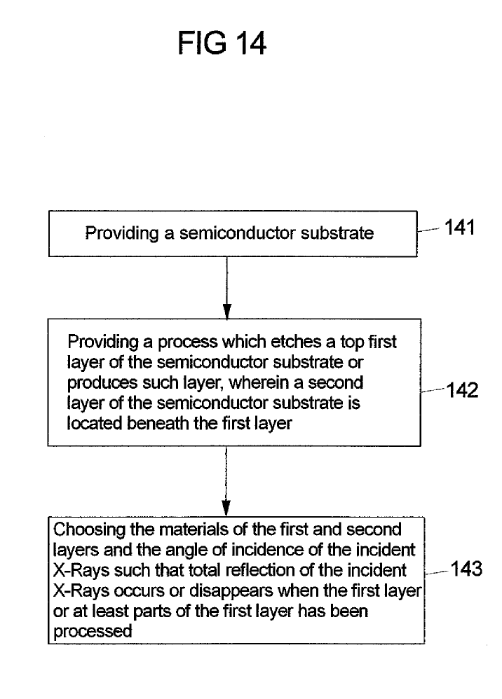

FIG. 14 shows a further embodiment of a method for manufacturing a semiconductor device using X-ray reflection to measure a change in volume of a substrate layer. In step 141, there is provided a semiconductor substrate. In step 142, there is provided a process which etches a top first layer of the semiconductor substrate or produces such layer, wherein a second layer of the semiconductor substrate is located beneath the first layer. In step 143, the materials of the first and second layers and the angle of incidence of the incident X-Rays are chosen such that total reflection of the incident X-Rays occurs or disappears when material of at least a part of the first layer has been processed (e.g., completely etched or deposited). The occurrence or disappearance of total reflection corresponds to an increase or drop in the intensity of the reflected X-Rays and indicates an end point of the etch or deposition process.

The person skilled in the art will recognize that the embodiments described above are just examples and that other variations in the use of fluorescence and/or reflection may be implemented to measure a change in volume of a semiconductor substrate layer and/or to provide for endpoint detection of etching or depositing processes. For example, other parts of the electromagnetic spectrum than X-rays may be used for fluorescence and reflection such as ultraviolet (UV) light. Also, etching may be implemented by any etching apparatus and method such as plasma etching, ion beam etching and electron-induced reactive etching.

What is claimed is:

1. A method of manufacturing a semiconductor device, the method comprising:
providing a semiconductor substrate; and
producing at least one structured layer in the semiconductor substrate, such producing comprising:
providing a process that changes volume of a portion of the semiconductor substrate, the portion of the semiconductor substrate comprising a region of a wafer, at least one layer of the semiconductor substrate or at least one layer deposited on the semiconductor substrate; and
measuring a change in volume of the portion of the semiconductor substrate using fluorescence.

2. The method according to claim 1, wherein measuring the change in volume comprises providing at least one incidence X-Ray beam and measuring an intensity of fluorescence radiation such that the use of fluorescence includes the use of X-Ray fluorescence.

3. The method according to claim 2, wherein a penetration depth of the incidence X-Rays into the at least one layer is tuned by varying an angle of incidence of the incidence X-Ray beam.

4. The method according to claim 2, wherein the incidence X-Ray beam is provided at grazing incidence.

5. The method according to claim 1, wherein a change in volume is detected locally by measuring fluorescence of local areas of the portion of the semiconductor substrate penetrated by an incidence electromagnetic beam.

6. The method according to claim 1, wherein fluorescence is measured at least at a first time and a second time during the process that changes the volume of the at least one layer, and a change in volume is determined by the difference in fluorescence between the first and second times.

7. The method according to claim 1, wherein there is provided a top first layer the volume of which is changed during the process, and an underlying second layer the volume of which is not changed during the process, wherein the first layer comprises a first material having a fluorescence radiation with a first wavelength, and the second layer comprises a second material having a fluorescence radiation with a second wavelength, and wherein both layers are subjected to electromagnetic radiation.

8. The method according to claim 7, wherein the fluorescence signal of at least one of the first and second layers is evaluated to determine the end point of the change-in-volume process.

9. The method according to claim 7, wherein
the change-in-volume process comprises an etching process;
the fluorescence signal of the second layer is measured; and
an end point is detected when the fluorescence signal of the second layer reaches a specified strength.

10. The method according to claim 9, wherein the reaching of a specified strength of the fluorescence signal of the second layer corresponds to a specific open area of the second layer produced by etching the first layer.

11. The method according to claim 9, wherein the etching process comprises a spacer etch in the course of a sublithographic patterning process and the reaching of a specified strength of the fluorescence signal of the second layer identifies an end point of the spacer etch in which a specific area of the second layer has been opened between the etched spacers.

12. The method according to claim 7, wherein
the change in volume process is a deposition process;
the fluorescence signal of the second layer is measured; and
an end point is detected when the fluorescence signal of the second layer reaches a specified minimum.

13. The method according to claim 12, wherein the reaching of a specified minimum of the fluorescence signal of the second layer corresponds to a specific thickness of the first deposited layer.

14. The method according to claim 1, wherein the process which changes the volume of at least a layer of the semiconductor substrate or a layer added to the semiconductor substrate is an etching process or a deposition process.

15. A method of manufacturing a semiconductor device, the method comprising:
providing a semiconductor substrate; and
producing at least one structured layer in the semiconductor substrate, such producing comprising:
providing a process that changes the volume of at least one layer of the semiconductor substrate or at least one layer deposited on the semiconductor substrate; and
measuring a change in volume of such at least one layer using reflection of electromagnetic waves.

16. The method according to claim 15, wherein
the substrate is irradiated with X-Rays;
X-Rays reflected by the substrate are measured, and a signal is provided indicative of the intensity of the reflected X-rays; and
the signal is evaluated to determine the change in volume of the at least one layer.

17. The method according to claim 16, wherein a decrease of the signal is associated with a reduction in thickness of the at least one layer and an increase of the signal is associated with a increase in thickness of the at least one layer.

18. The method according to claim 15, further comprising providing a top first layer of the semiconductor substrate and an second layer of the semiconductor substrate beneath the first layer, the two layers having a different refractive index.

19. A method of manufacturing a semiconductor device, the method comprising:
providing a semiconductor substrate;
providing a top first layer of the semiconductor substrate and a second layer of the semiconductor substrate beneath the first layer, the two layers having a different refractive index for X-Ray radiation; and
etching the first layer of the semiconductor substrate, and during etching:
irradiating the substrate with X-Rays;
measuring the X-Rays reflected by the substrate, and providing a signal indicative of the reflected X-rays;
determining a change in the signal; and
associating an end point of the etching process with the change in the signal.

20. The method according to claim 19, wherein the signal experiences a drop-off that corresponds to a drop in the reflected X-Ray intensity, and wherein this drop-off is associated with an end point of the etching process.

21. The method according to claim 19, wherein
the material of the first layer is chosen such that it has a first critical grazing angle of total reflection for X-Ray radiation;
the material of the second layer is chosen such that it has a second critical grazing angle of total reflection for X-Ray radiation, the second critical angle being smaller than the first critical angle; and
X-Rays are irradiated at the substrate at a grazing angle of incidence that is smaller than the first critical angle of total reflection for the material of the first layer and larger than the second critical angle of total reflection for the material of the second layer.

22. The method according to claim 21, wherein,
before material of the first layer is etched away, total reflection of the incident X-Rays occurs at this material; and
when material of the first layer is etched away, the X-Rays are incident on the material of the second layer where they do not experience total reflection such that there occurs a drop in reflected intensity.

23. The method according to claim 19, wherein etching includes etching of lines and spaces or a line etch and the X-Rays are irradiated in a direction parallel to the lines and spaces or lines.

24. A method of manufacturing a semiconductor device, the method comprising:
providing a semiconductor substrate;
providing a process which etches a top first layer of the semiconductor substrate or produces such layer, wherein a second layer of the semiconductor substrate is located beneath the first layer, wherein
the materials of the first and second layers and the angle of incidence of the incident X-Rays are chosen such that total reflection of the incident X-Rays occurs or disappears when material of the first layer or at least parts of the first layer has been processed,
the occurrence or disappearance of total reflection corresponding to an increase or drop in the intensity of the reflected X-Rays.

25. An apparatus for the manufacturing of semiconductor devices, the apparatus comprising:
means for changing the volume of at least one layer of a semiconductor wafer or at least one layer deposited on the semiconductor wafer;
an X-Ray radiation source;
an X-Ray detection device detecting and measuring a signal indicative of the intensity of X-Rays reflected or emitted by fluorescence by the semiconductor wafer when irradiated with X-Rays by the X-Ray radiation source; and
evaluating means for associating the signal with the change in volume process.
